(19) United States
(12) Patent Application Publication
(10) Pub. No.: US 2012/0119658 A1
(43) Pub. Date: May 17, 2012

(54) System and Method for Controlling White Light

(75) Inventor: Donald Louis McDaniel, North Andover, MA (US)

(73) Assignee: Luminus Devices, Inc., Billerica, MA (US)

(21) Appl. No.: 12/948,747

(22) Filed: Nov. 17, 2010

(51) Int. Cl. H05B 37/02; H05K 13/00

(52) U.S. Cl. 315/151; 315/294; 29/592.1

(57) ABSTRACT

A system and method for tuning white light while reducing manufacturing costs.

### CROSS-REFERENCE TO RELATED APPLICATIONS

This application claims priority under 35 U.S.C. §119 to the following U.S. Provisional Patent Applications: ______, filed May 10, 2010, under the title “A System and Method for Controlling White Light.”

### BACKGROUND OF THE INVENTION

1. Field of the Invention

The present embodiments are generally drawn towards systems and methods for controlling white light and more specifically tunable systems that control a desired color temperature and intensity output of white light.

2. Description of the Prior Art

Light perceived by the eye is generally different than light recorded by film. As a result, the natural eye will perceive the light to be one color, but when the recorded film is replayed the coloring will be off. As a result, television and movie producers are very particular about the color of white light they use when shooting film. If the color is too green it could make an actor or anchor look pale and not natural. Similar results occur if the light is too pink or red, thus if the problem is not properly corrected undesired results occur—maybe to the tune of that actor or anchor switching careers.

Film can be calibrated to various color temperatures; however, if the color temperature of the light changes during the recording that calibration may become extremely difficult or impossible. A number of factors may cause the color temperature of the light to change including cloud cover and position of the sun in the sky. Having a tunable white light system is thus desirable to have the ability to recreate the lighting scheme during the film production.

Within physics and the lighting industry, three dimensional color spaces have been developed to quantify colors. The CIE XYZ color space is an example of one such model, utilizing one luminance dimension and two chromaticity dimensions—akin to hue and colorfulness—to identify a color at the convergence of the corresponding values. However, to provide a more intelligible model, two dimensional color diagrams, such as the CIE 1931 color space chromaticity diagram, have been employed that eliminate the luminance dimension and plot the color spectrum solely against the two chromaticity dimensions, denoted by the x and y axis. Because colors vary, as perceived by the human eye, according to the wavelength of the light, the color space in the CIE 1931color space chromaticity diagram is bounded by the wavelengths of the visible light spectrum, producing the tongue-shaped gamut of human vision illustrated in the diagram. Any distinct chromaticity coordinate in the color space can thus be specified by x and y chromaticity coordinates.

Of particular significance within the color space is the blackbody curve, also called the Planckian locus. A pure blackbody absorbs all electromagnetic radiation to which it is exposed, while any visible light emitted from the blackbody is purely a function of its temperature. While true blackbodies do not exist on Earth, advancements in the field have produced materials and devices that can closely approximate the qualities of blackbodies. The blackbody curve is a path representing the colors that an incandescent blackbody would radiate in a particular chromaticity space as the temperature of the blackbody varies. The blackbody glows red at lower temperatures and bluish white at extremely high temperatures. Higher temperatures along the locus are referred to as cool white while lower temperatures are referred to as warm white. In between these temperature extremes along the Planckian locus, the blackbody emits various hues of white light. Many applications require the ability to tune the color of emitted white light to either side of the blackbody curve. A light source's color temperature, stated in units of absolute temperature (K), is the temperature of an ideal blackbody radiator that radiates light of comparable chromaticity to that light source.

In order to tune the color temperature produced, some prior art systems include using a number of filters to control the color temperature emitted by a particular white emitting light while others use multiple non-white lights such as red, green and blue to mix and match the color so as to obtain the desired output. Manufacturing such systems can be complex and bulky while using filters causes inefficiencies as one is effectively reducing the amount of light output of a system.

### SUMMARY OF THE INVENTION

A system for tuning white light comprising a package having at least three light-emitting die attached to the package. At least two of the light-emiting die emit light having a separate and distinct correlated color temperature. At least one of the light-emitting die emits light having a chromaticity coordinate above the black body curve and each light-emitting die contains at least one light emission region. A controller is connected to each light-emitting die, wherein the light output of each light-emitting die is individually controlled.

In one embodiment the controller can tune the output of the light by using a look-up calibration table.

In one embodiment the controller can tune the output of the light by using a sensor input device that detects correlated color temperature (COT) and the distance on the x and y axis, or “delta uv” on some diagrams, from the Planckian locus.

Other aspects, embodiments and features of the invention will become apparent from the following detailed description of the invention when considered in conjunction with the accompanying figures. The accompanying figures are schematic and are not intended to be drawn to scale. In the figures, each identical or substantially similar component that is illustrated in various figures is represented by a single numeral or notation.

For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF THE DRAWINGS

FIGS. 1a-d show a white light system comprising a package of light-emitting dies and emission regions.

FIG. 2 shows light-emitting dies each having a plurality of emission regions.

FIG. 3 shows the Planckian locus on the CIE 1931 color space chromaticity diagram.

FIG. 4 shows the area enclosed by two sets of three chromaticity coordinates near a blackbody curve.

FIG. 5 shows quadrants along a blackbody curve that create bins based on the output of individual light-emitting dies.

FIG. 6 shows a tunable white light system

FIG. 7 shows a method for producing a tunable white light system.

### DETAILED DESCRIPTION OF THE PREFERRED EMBODIMENT

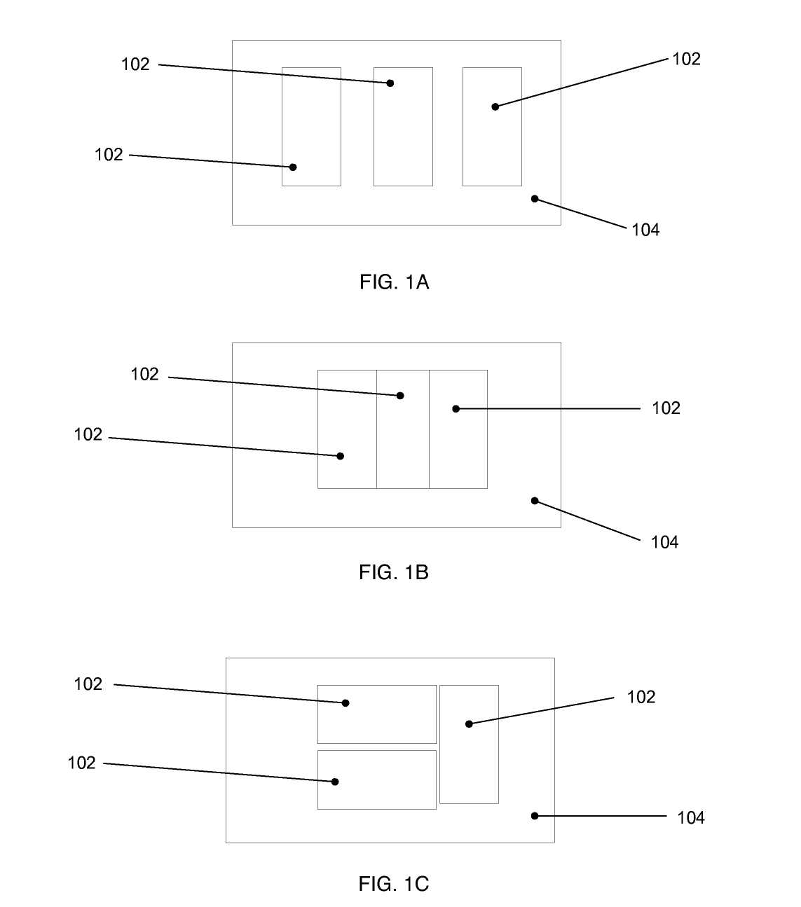

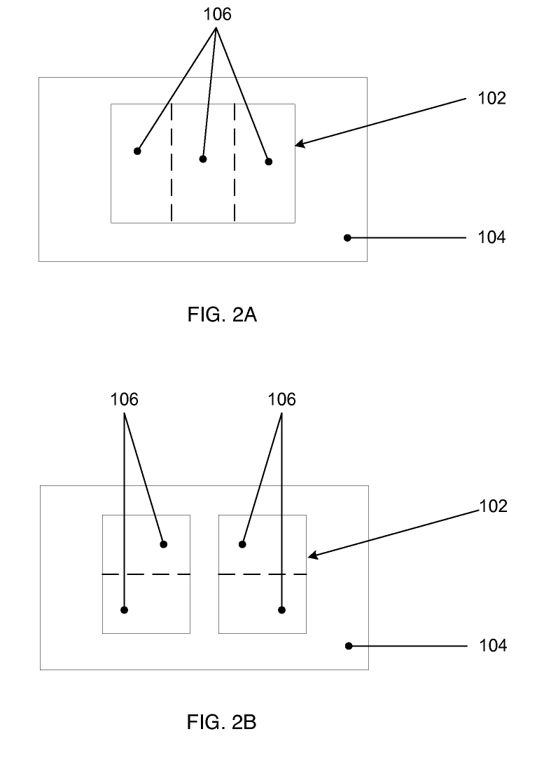

FIGS. 1a-c are basic schematics showing embodiments of white-light emitting devices having a configuration of three closely-packed light-emitting dies 102. Other embodiments not shown may be comprised of more light-emitting dies. Each light-emitting die 102 generally has at least one emission region 106 emitting light characterized by a distinct chromaticity coordinate on a chromaticity diagram. FIGS. 2a-b illustrate embodiments where light-emitting dies 102 have more than one emission region 106. For instance, FIG. 2a illustrates a light-emitting die 102 on a package 104 having three emission regions 106. FIG. 2b illustrates a package containing two light-emitting dies 102 with each light-emitting die 102 having two emission regions 106 totaling four emission regions for the package. Each emission region 106 may have a distinct and separate CCT and uv deviation (or x,y chromaticity coordinate), but in some embodiments there may be multiple emission regions within the package having similar or the same CCT and uv deviation emission specifications.

Generally when using a three-point tunable white-light system it is advantageous to provide two of those chromaticity coordinates above the Planckian locus and one below. The single point below the Planckian locus can be either on the cool white side (6500K) or the warm white side (2700K) range of the curve. This is so in part because of the curvature of the Planckian locus. Having such an arrangement with two points above this curve generally allows for a greater tunable range along the Planckian curve.

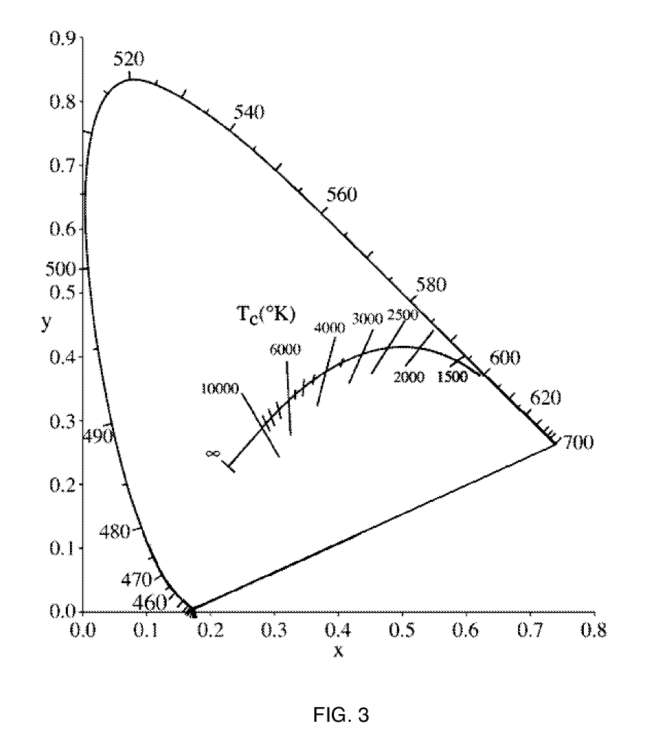

FIG. 3 shows the CIE 1931 color space chromaticity diagram illustrating a visual perception of the correlated color temperatures surrounding the Planckian locus. Within the two-dimensional color space, a line connecting any two chromaticity coordinates passes through all colors that can be achieved by mixing the colors of the two source chromaticity coordinates. Moreover, the area bounded by any three chromaticity coordinates represents all colors that can be achieved by mixing the colors of the three source chromaticity coordinates. Likewise, the area bounded by any four chromaticity coordinates represents all colors that can be achieved by mixing the colors of the four source chromaticity coordinates.

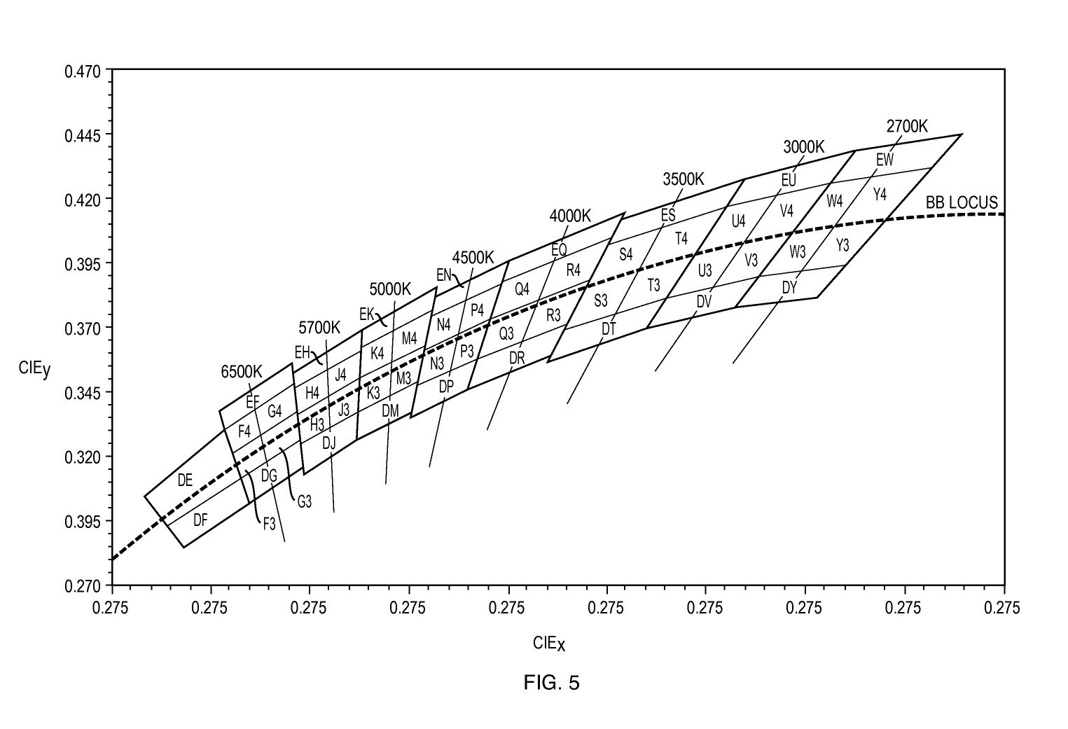

Chromaticity coordinates near the Planckian locus are of particular interest because of their proximity to the desirable white regions being sought after. In some embodiments the chromaticity coordinates near the Planckian locus may individually already be a desirable emission point. Additionally, current semiconductor materials used to create light near the Planckian locus generally produce emission points having a color rendering index (CRI) that is high in value. For example, in some chromaticity coordinates in the white regions as shown in FIG. 5 may have a CRI greater than 80, greater than 85, greater than 90 and greater than 95. Additionally, the tolerances required to produce white-emitting or near-white light emission dies allows for lower manufacturing costs as well as a reduced system cost. Near white emission chromaticity coordinates provide a higher efficacy over an RGB color system; plus, they provide a tuning gamut that is more usable and desirable.

For instance, when shining a light source on an object that object will reflect and absorb light in a particular manner. If the bandgap of light has high peaks at discrete wavelengths the object may look unnatural as compared with sunlight or an incandescent bulb, which have a much broader bandgap or spectrum. Using the near-white sources as described herein, allows objects to appear closer to how they would in natural light or light emanated from a perfect black body radiator. Applications range is using this kind of a system from restaurants to recording television and movie productions. Any time it is important for an illuminated area to portray objects as they would under current lighting standards. Particularly, if ambient light may affect the coloring of objects or people.

Chromaticity coordinates close to the Planckian locus, i.e., having a low delta uv from the Planckian locus may be referred to as near-white or near-white colors. As stated another way near-white color points or near-white chromaticity coordinates are those having a deviation along the y-axis of equal to or less than 0.05 off the Planckian curve. This deviation in the y-axis is based on the 1931 CIE color space graph. It follows that an emission region on a light-emitting die 102 that emits light characterized by a chromaticity coordinate near the Planckian locus can be characterized as a “near-white” emission region.

FIG. 3 illustrates that chromaticity coordinates above the locus tend to have more of a green color while those below have more of a pink or red color. The cool white side tends to have more blue while the warm white side has more orange and yellow color. Though the near-white chromaticity coordinates used herein may have appear to have a shade or tint of blue, red, yellow, green or otherwise, they are not actual red, green, yellow, blue or other colors.

A system with more distinct color points, such as an RGB system, often requires more complex mixing and the spectrum of light as viewed may change based on the angle of observance. Furthermore, objects may appear off in color as compared to being shown in natural light because of the high peaks at discrete wavelengths as mentioned above. These discrete wavelengths may be absorbed or reflected differently than a system having broad spectrum of wavelengths. For example, an object that happens to absorb the red discrete wavelength of an RGB system may look more pale or green as compared with a broad spectrum emission system such as the one described herein. Thus, near-white color points placed in a tunable system achieve the desired results sought for over a tunable RGB system.

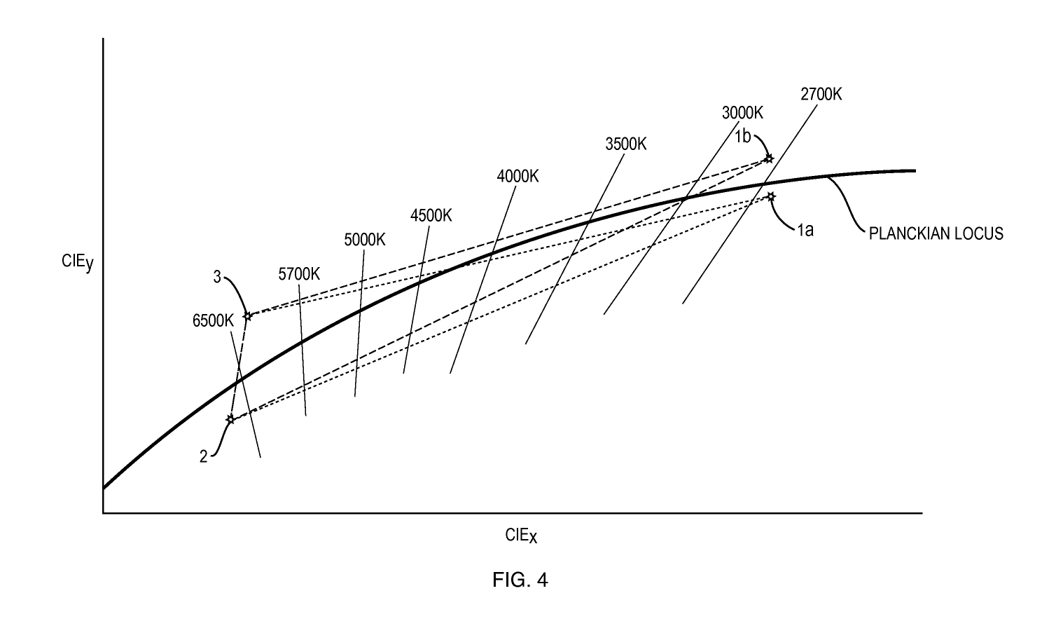

The combination of the distinct emission regions contained in the system creates a specific range of white light along the Planckian locus as shown in FIG. 4. Using the example shown in FIG. 4, when analyzing chromaticity coordinates 1a, 2, and 3 it can be seen that such a range of white light that can be produced along the Planckian locus is limited from about 4000K to 6500K. However, by exchanging point 1a with 1b, which lies above the Planckian locus, the range is now extended from approximately 3000K to 6500K. As mentioned above, generally having two points above and at least one below the curve is advantageous. In other embodiments, it is contemplated using four chromaticity coordinates. The area of tunability thus becomes the shape of a rectangle, trapezoid, or other four-sided polygon shape. Thus, if the four points 1a, 1b, 2, and 3 as shown in FIG. 4 were used together the range along the black body curve as well as the range above and below the black body curve near the 1a and 1b points would be increased. Other embodiments may yet include five or more chromaticity coordinate emission regions.

Examples of CCT tunable ranges sought for in the industry include: 3000K-5700K in entertainment, 2700K-3300K in residential, 3000K-4500K in office environments, 2700K-4500K and 4000K-5700K in hospitality, and 4000K-5700K for commercial applications. Having a tunable white light system that can mix and match various chromaticity coordinates in package suitable for a parituclar lighting industry allows for reduced manufacturing costs as well as reduced and simpler white lighting systems.

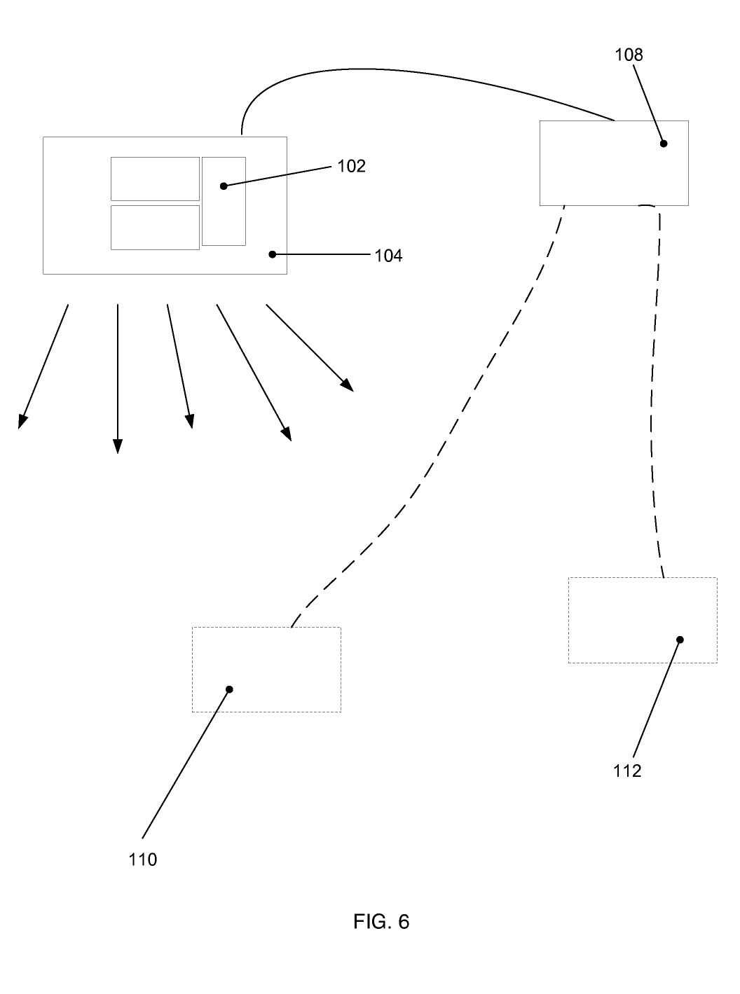

FIG. 6 shows a method for using the tunable white-light system. For example, the system produces a particular white light closer to the warm white end of the curve. A cooler white temperature is desired so the controller 108 adjusts the output levels of each emission region 106 contained on the light-emitting die(s) 102 to shift the originally warm white light over to a cooler white temperature along the curve. This controller 108 can adjust the white light output by manually adjusting each emission region 106. A predetermined input calibration table 112 based on each emission region's correlated color temperature (CCT) may be incorporated into the controller 108. This calibration table 112 can be used either for reference purposes when manually adjusting each individual emission region 106 or to simplify the input controls in order to adjust all of the emission regions synchronously.

Some embodiments include emission regions close enough in proximity wherein additional mixing optics are not necessary. Other embodiments include using mixing optics and thus do not require the emission regions to be as close in physical location. It is contemplated that a tunable white system having a particular tuning range may be created using at least three near-white color emission regions. Additionally, the type of light source sought for, such as a direct or diffuse lighting system, may also determine whether and what kind of mixing optics are used.

The controller 108 can be adapted to take input data from a sensor device 110 in real time that adjusts the light output to a desired CCT and/or x,y chromaticity coordinate. Such a sensor 110 can be implemented either manually or automatically into the system. For instance, the sensor 110 may be a part of a feedback control loop that displays an output as a user manually adjusts the output or the sensor 110 can be implemented in a feedback control loop that automatically adjusts the output CCT to a preset value. The preset CCT value may reside on or off the Planckian curve as desired by the user.

FIG. 5 shows a Planckian locus where the surrounding areas have been divided up into several quadrants with each quadrant receiving a particular bin indicator. Light-emitting dies with emission regions producing white light in those particular quadrants can then be placed into corresponding bins. This binning process allows for greater flexibility when producing a particular tunable white-light system. For instance, manufacturers can predetermine the desired ranges needed and produce light-emitting dies with such emission regions into the corresponding bins. The tolerances allow for greater flexibility in the manufacturing process. Because the emission region(s) of light-emitting dies can be tested and determined during the manufacturing process, even light-emitting dies with emission regions outside their individual design tolerances can still be utilized so long as its emission region falls within the chromaticity coordinate specifications of one of the bins. This decreases waste in the manufacturing process.

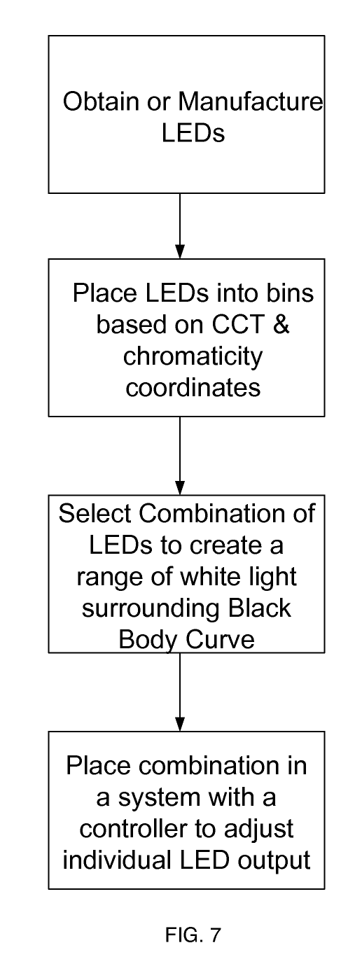

FIG. 7 shows a process of efficiently utilizing a manufacturing process of white light-emitting die chips. First, light-emitting die chips having at least one near-white emission region are manufactured or obtained from a manufacturing process. The CCT and deviation of each emission region are tested. The light-emitting dies are then placed into bins according to their CCT. A selection of light-emitting dies from distinct bins is then used to create a system with a specified range of CCT and deviation (on both the green and pink side of the curve). The selected light-emitting dies are then placed into a system that enables individual control of each emission region. This binning and selection process allows for a lower-cost white light system as well as a white light system that is adjustable. Controllers with calibration tables and/or sensor input devices and capabilities may then be connected to the tunable white-light system.

The light-emitting dies in this system may have emission surfaces greater than 1 mm², greater than 3 mm², 9 mm² or 12 mm². Likewise, each distinct emission region having a distinct CCT and delta uv (deviation from the Planckian curve) may comprise a region greater than 1 mm², greater than 3 mm², 9 mm² or 12 mm².

As noted above, these methods and systems are not limited to a specified number of light-emitting die chips, they take advantage of yield distribution when producing white light-emitting die chips, and they allow for a flexible white light system that can be tunable to a desired color temperature and delta uv above, below, or on the Planckian curve.

The above description is merely illustrative. Having thus described several aspects of at least one embodiment of this invention including the preferred embodiments, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A system for tuning white light comprising:
a package;
at least three light-emitting die attached to the package, wherein at least two of the light-emiting die emit light having a separate and distinct correlated color temperature, wherein at least one of the light-emitting die emits light having a chromaticity coordinate above the black body curve, and wherein each light-emitting die contains at least one light emission region; and
a controller connected to each light-emitting die, wherein the light output of each light-emitting die is individually controllable.

2. The system of claim 1, further including a calibration table.

3. The system of claim 1, further including a sensor device in communication with the controller.

4. The system of claim 1, wherein one of the near-white emission regions emits a correlated color temperature greater than 5700 K.

5. The system of claim 1, wherein one of the near-white emission regions emits a correlated color temperature above the black body curve at a temperature less than 2700 K.

6. The near-white emission regions of claim 1, wherein each near-white emission region has a CRI greater than 80.

7. The system of claim 1, wherein each light-emitting die has an emission surface greater than 1 mm².

8. The system of claim 1, wherein each near-white emission region is greater than 1 mm².

9. The system of claim 1, wherein the white light output is tunable in the range of 2700 K to 6500 K.

10. The system of claim 1, wherein the near-white emission regions have a chromaticity value in the y direction equal to or less than 0.05 away from the black body curve.

11. The system of claim 1, further comprising a fourth near-white emission region.

12. The system of claim 1, wherein two near-white emission regions are contained on a single light-emitting die.

13. The system of claim 1, wherein three near-white emission regions are contained on a single light-emitting die.

14. The system of claim 1, wherein the white light output is tunable in the range of 3000K to 5700K.

15. The system of claim 1, further comprising a second light-emitting die.

16. A method for producing a tunable white light system comprising:
obtaining light-emitting die having at least one near-white emission region;
determining the CCT and chromaticity coordinate of each near-white emission region;
placing the light-emitting die in bins based on CCT and chromaticity coordinate values;
selecting a combination of light-emitting die from the bins wherein a specified range of white light is created; and
placing the selected light-emitting die in a single package.

17. The method of claim 16, further including attaching a controller to the single package.

18. The method of claim 17, further including providing a calibration table.

19. The method of claim 17, further including providing a sensor input device in communication with the controller.

20. The method of claim 16, wherein the near-white emission regions have a chromaticity value in the y direction equal to or less than 0.05 away from the black body curve.
